(19) United States
(12) Patent Application Publication
(10) Pub. No.: US 2026/0059809 A1
(43) Pub. Date: Feb. 26, 2026

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US); Sundar Babu Isukapati, Gilbert, AZ (US); Kevin Speer, Bentonville, AR (US)

(73) Assignee: Microchip Technology Incorporated, Chandler, AZ (US)

(21) Appl. No.: 19/070,053

(22) Filed: Mar. 4, 2025

Related U.S. Application Data
(60) Provisional application No. 63/685,441, filed on Aug. 21, 2024.

(51) Int. Cl. H10D 62/10; H10D 30/01; H10D 30/66; H10D 62/17

(52) U.S. Cl. CPC H10D 62/105; H10D 30/0291; H10D 30/66; H10D 62/393

(57) ABSTRACT

A transistor comprising a drift layer formed within a substrate. A plurality of well implant layers layer formed into the drift layer with at least one of the well implant layers having a lateral well extension within the drift layer. A plurality of gate implant layers formed into the drift layer and formed over a portion of the respective well implant layer. A source implant layer formed into the drift layer. At least a portion of the source implant layer over a portion of the lateral well extension of the well implant layer. A plurality of gate contacts operatively connected to the respective gate implant layer. A source contact operatively connected to the source implant layer.

### CROSS-REFERENCE TO RELATED APPLICATION

The present application claims priority to U.S. Provisional Patent Application No. 63/685,441 filed on Aug. 21, 2024, the contents of which are hereby incorporated by reference in their entirety.

### TECHNICAL FIELD

The present disclosure relates generally to transistors, and more specifically to Junction Field Effect Transistors and methods for manufacturing same to improve the performance of the transistor.

### SUMMARY

According to an aspect of one or more examples, there is provided a transistor that may include a substrate, a drift layer formed within the substrate, a plurality of well implant layers formed into the drift layer, at least one of the well implant layers having a lateral well extension within the drift layer, a plurality of gate implant layers formed into the drift layer and formed over a portion of the respective well implant layer, a source implant layer formed into the drift layer, at least a portion of the source implant layer over a portion of the lateral well extension of the well implant layer, a plurality of gate contacts operatively connected to the respective gate implant layers, and a source contact operatively connected to the source implant layer. The transistor may comprise a planar surface over the source implant layer and the plurality of gate implant layers. The substrate may comprise a first concentration of a first type dopant. The drift layer may comprise a second concentration of the first type dopant, the second concentration is less than the first concentration. The plurality of well implant layers may comprise a third concentration of a second type dopant. The plurality of gate implant layers may comprise a fourth concentration of the second type dopant, the fourth concentration is greater than the third concentration. The source implant layer may comprise a fifth concentration of the first type dopant. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided method of manufacturing a transistor. The method may include providing a substrate, forming a drift layer within the substrate, implanting a plurality of well implant layers into the drift layer, at least one of the well implant layers having a lateral well extension within the drift layer, implanting a plurality of gate implant layers into the drift layer and formed over a portion of the respective well implant layer, implanting a source implant layer into the drift layer, at least a portion of the source implant layer over a portion of the lateral well extension of the well implant layer, forming a plurality of gate contacts operatively connected to the respective gate implant layer, and forming a source contact operatively connected to the source implant layer. The transistor may comprise a planar surface over the source implant layer and the plurality of gate implant layers. The substrate may comprise a first concentration of a first type dopant. The drift layer may comprise a second concentration of the first type dopant, the second concentration is less than the first concentration. The plurality of well implant layers may comprise a third concentration of a second type dopant. The plurality of gate implant layers may comprise a fourth concentration of the second type dopant, the fourth concentration is greater than the third concentration. The source implant layer may comprise a fifth concentration of the first type dopant. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 is a cross sectional view of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

FIG. 2D is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

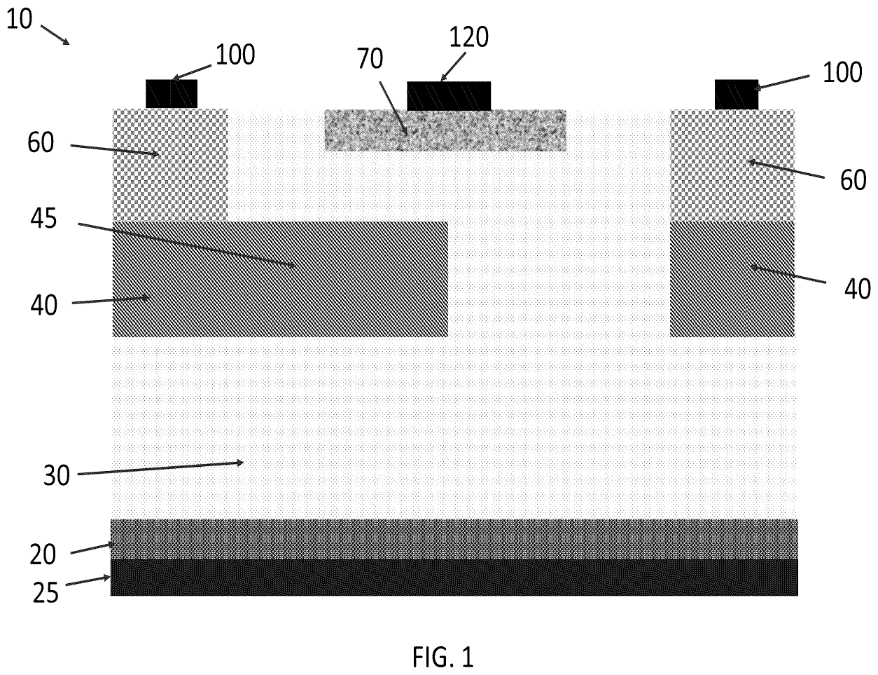

FIG. 1 shows a cross sectional view of a transistor 10 according to one or more examples. Transistor 10 may represent, and may be called a junction field effect transistor, without limitation. The example transistor 10 (junction field effect transistor) of FIG. 1 may include a substrate 20. The substrate 20 shown in FIG. 1 may have a first concentration of a first type dopant, e.g., 5E18 (i.e. 5×10¹⁸). A drain contact 25 may be formed at a first side of the substrate 20. The drain contact may be made from a metal, polysilicon, or other suitable material. The example transistor 10 (junction field effect transistor) of FIG. 1 may include a drift layer 30 formed within the substrate 20 at a second side of the substrate 20. The second side of the substrate 20 is opposite the first side of the substrate 20 where the drain contact 25 was formed. The drift layer 30 may comprise a second concentration of the first type dopant. The second concentration of first type dopant in the drift layer 30 may be less than the first concentration of first type dopant in the substrate 20. The example transistor 10 (junction field effect transistor) of FIG. 1 may include a plurality of well implant layers 40 formed into the drift layer 30. At least one of the well implant layers 40 may have a lateral well extension 45 within the drift layer 30. The plurality of well implant layers 40 may comprise a third concentration of a second type dopant that may have a peak doping in the range 1E17 to 5E18. The example transistor 10 (junction field effect transistor) of FIG. 1 may include a plurality of gate implant layers 60 formed into the drift layer 30. The plurality of gate implant layers 60 may comprise a fourth concentration of the second type dopant. The fourth concentration of the second type dopant of the plurality of gate implant layers 60 may be greater than the third concentration of the second type dopant of the plurality of well implant layers 40. The example transistor 10 (junction field effect transistor) of FIG. 1 may include a source implant layer 70 formed into the drift layer 30. At least a portion of the source implant layer 70 may be over a portion of the lateral well extension 45 of the well implant layer 40. The source implant layer 70 may comprise a fifth concentration of the first type dopant. The example transistor 10 (junction field effect transistor) of FIG. 1 may comprise a planar surface over the source implant layer 70 and the plurality of gate implant layers 60. The example transistor 10 (junction field effect transistor) of FIG. 1 may include a plurality of gate contacts 100 operatively connected to the respective gate implant layer 60. The plurality of gate contacts 100 may be made from a metal, polysilicon, or other suitable material. The example transistor 10 (junction field effect transistor) of FIG. 1 may include a source contact 120 operatively connected to the source implant layer 70. The source contact 120 may be made from a metal, polysilicon, or other suitable material. When a gate-to-source voltage is applied to the transistor 10 (junction field effect transistor) of FIG. 1, current flows through a channel created around the lateral well extension 45 of the well implant layer 40 from the source contact 120 to the drain contact 25.

In one example of the example transistor 10 (junction field effect transistor) of FIG. 1, the first type dopant may be an n-type dopant and the second type dopant may be a p-type dopant. In another example of the example transistor 10 (junction field effect transistor) of FIG. 1, the first type dopant may be a p-type dopant and the second type dopant may be an n-type dopant.

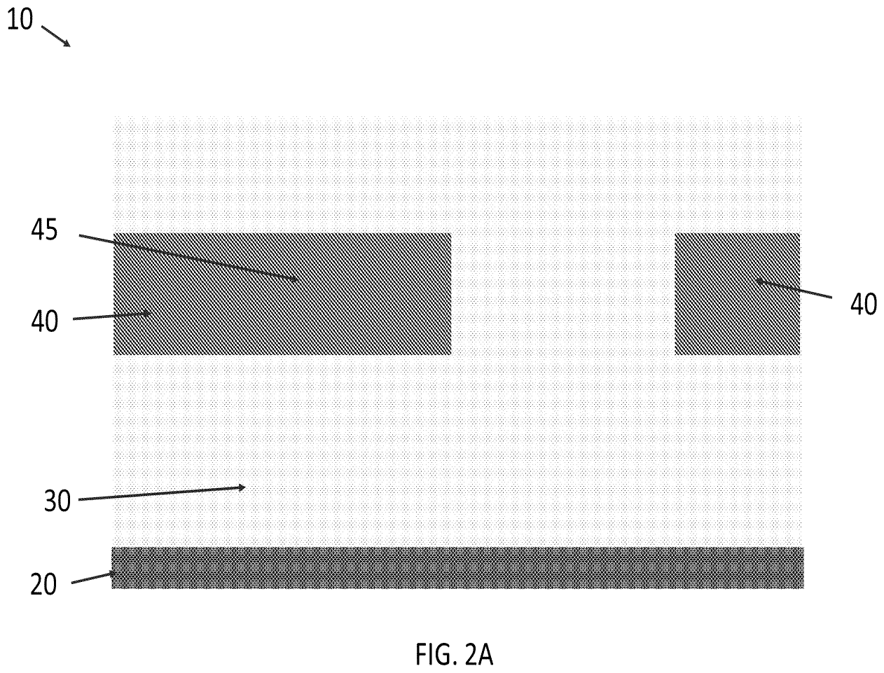

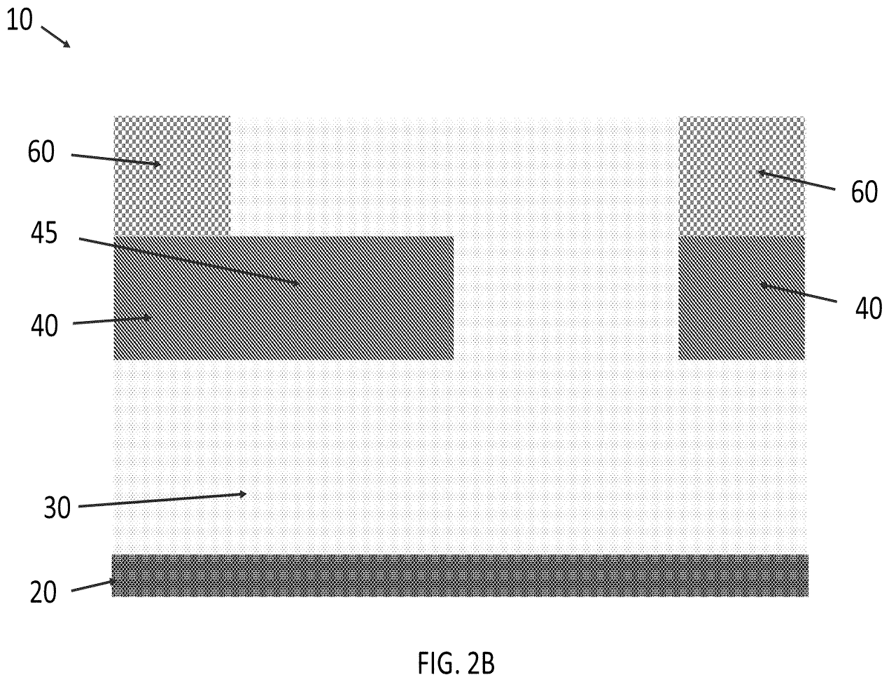

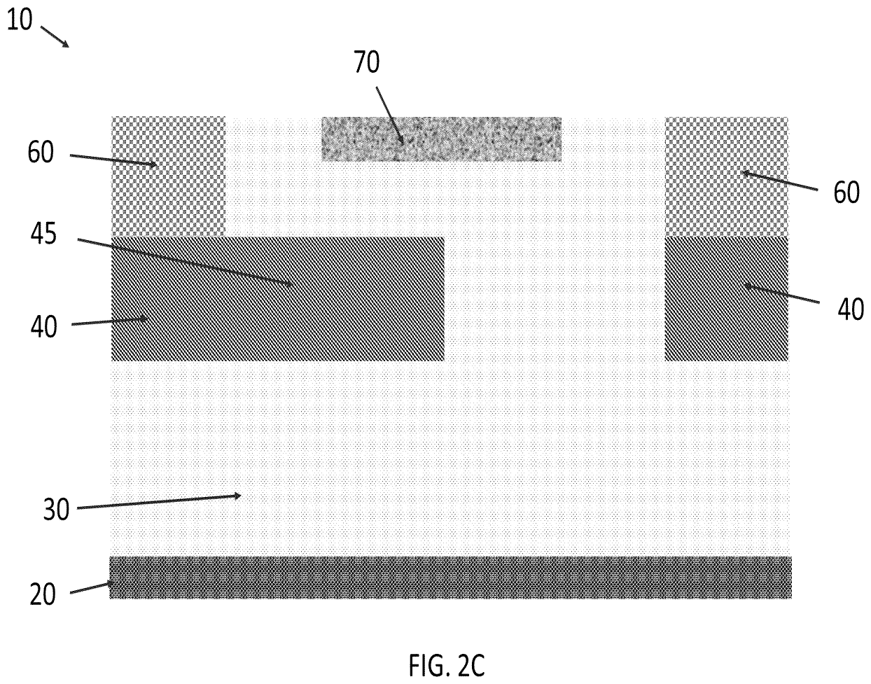

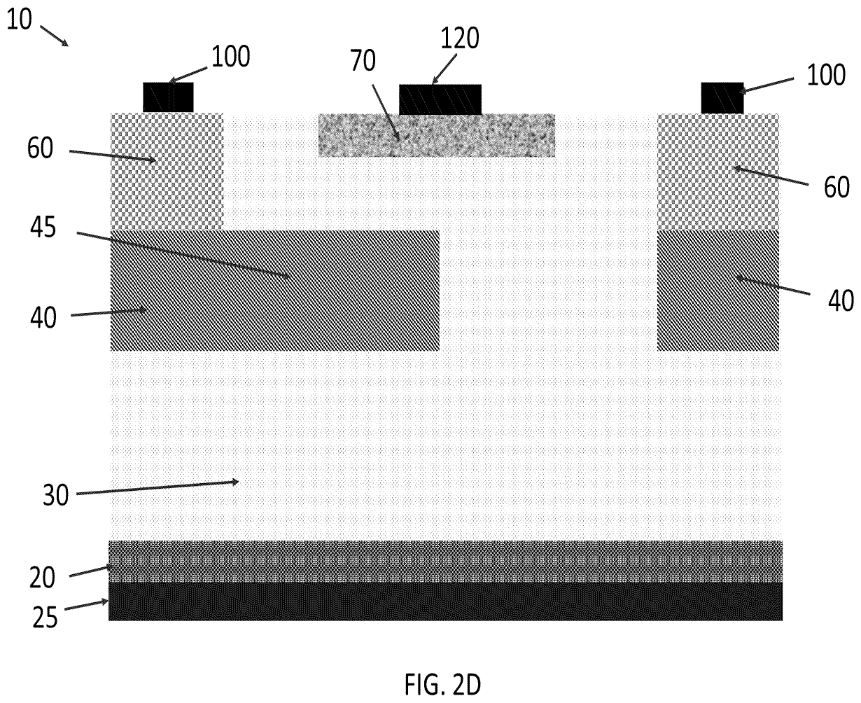

FIGS. 2A-2D show a method of manufacturing a transistor 10 according to one or more examples. Although the example method shown in FIGS. 2A-2D include steps shown in a particular order, the steps may be performed in a different order, and may include additional steps that are not explicitly shown.

FIG. 2A is a cross sectional view of some of the steps in a method of manufacturing a transistor 10 according to one or more examples. Transistor 10 may represent, and may be called a junction field effect transistor, without limitation. In FIG. 2A, the example method may include a substrate 20. The substrate 20 may have a first concentration of a first type dopant, e.g., 5E18 (i.e. 5×10¹⁸). In FIG. 2A, the method may include forming a drift layer 30 within the substrate 20. The drift layer 30 may comprise a second concentration of the first type dopant. The second concentration of first type dopant in the drift layer 30 may be less than the first concentration of first type dopant in the substrate 20. In FIG. 2A, the method may include implanting a plurality of well implant layers 40 into the drift layer 30. At least one of the well implant layers 40 may have a lateral well extension 45 within the drift layer 30. The plurality of well implant layers 40 may comprise a third concentration of a second type dopant that may have a peak doping in the range 1E17 to 5E18.

FIG. 2B is a cross sectional view of some of the steps in a method of manufacturing a transistor 10 according to one or more examples. In FIG. 2B, the method may include implanting a plurality of gate implant layers 60 into the drift layer 30. The plurality of gate implant layers 60 may comprise a fourth concentration of the second type dopant. The fourth concentration of the second type dopant of the plurality of gate implant layers 60 may be greater than the third concentration of the second type dopant of the plurality of well implant layers 40.

FIG. 2C is a cross sectional view of some of the steps in a method of manufacturing a transistor 10 according to one or more examples. In the method step shown in FIG. 2C, the method may include implanting a source implant layer 70 into the drift layer 30. At least a portion of the source implant layer 70 may be over a portion of the lateral well extension 45 of the well implant layer 40. The source implant layer 70 may comprise a fifth concentration of the first type dopant. In FIG. 2C, the method may comprise forming a planar surface over the source implant layer 70 and the plurality of gate implant layers 60.

FIG. 2D is a cross sectional view of some of the steps in a method of manufacturing a transistor 10 according to one or more examples. In FIG. 2D, the method may include forming a plurality of gate contacts 100 operatively connected to the respective gate implant layer 60. The plurality of gate contacts 100 may be made from a metal, polysilicon, or other suitable material. In FIG. 2D, the method may include forming a source contact 120 operatively connected to the source implant layer 70. The source contact 120 may be made from a metal, polysilicon, or other suitable material. In FIG. 2D, the method may include forming a drain contact 25 operatively connected to the substrate 20. The drain contact 25 may be made from a metal, polysilicon, or other suitable material. When a gate-to-source voltage is applied to the transistor 10 (junction field effect transistor) of FIGS. 2A-2D, current flows through a channel created around the lateral well extension 45 of the well implant layer 40 from the source contact 120 to the drain contact 25.

In one example of the example transistor 10 (junction field effect transistor) of FIGS. 2A-2D, the first type dopant may be an n-type dopant and the second type dopant may be a p-type dopant. In another example of the example transistor 10 (junction field effect transistor) of FIGS. 2A-2D, the first type dopant may be a p-type dopant and the second type dopant may be an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
a drift layer formed within the substrate;
a plurality of well implant layers formed into the drift layer, at least one of the well implant layers having a lateral well extension within the drift layer;
a plurality of gate implant layers formed into the drift layer and formed over a portion of the respective well implant layer;
a source implant layer formed into the drift layer, at least a portion of the source implant layer over a portion of the lateral well extension of the well implant layer;
a plurality of gate contacts operatively connected to the respective gate implant layer; and
a source contact operatively connected to the source implant layer.

2. The transistor of claim 1 comprises a planar surface over the source implant layer and the plurality of gate implant layers.

3. The transistor of claim 1, wherein the substrate comprises a first concentration of a first type dopant.

4. The transistor of claim 3, wherein the drift layer comprises a second concentration of the first type dopant, the second concentration is less than the first concentration.

5. The transistor of claim 4, wherein the plurality of well implant layers comprise a third concentration of a second type dopant.

6. The transistor of claim 5, wherein the plurality of gate implant layers comprise a fourth concentration of the second type dopant, the fourth concentration is greater than the third concentration.

7. The transistor of claim 6, wherein the source implant layer comprises a fifth concentration of the first type dopant.

8. The transistor of claim 7, wherein the first type dopant comprises an n-type dopant and the second type dopant comprises a p-type dopant.

9. The transistor of claim 7, wherein the first type dopant comprises a p-type dopant and the second type dopant comprises an n-type dopant.

10. A method of manufacturing a transistor, the method comprising:
providing a substrate;
forming a drift layer within the substrate;
implanting a plurality of well implant layers into the drift layer, at least one of the well implant layers having a lateral well extension within the drift layer;
implanting a plurality of gate implant layers into the drift layer and formed over a portion of the respective well implant layer;
implanting a source implant layer into the drift layer, at least a portion of the source implant layer over a portion of the lateral well extension of the well implant layer;
forming a plurality of gate contacts operatively connected to the respective gate implant layer; and
forming a source contact operatively connected to the source implant layer.

11. The method of claim 10 comprises forming a planar surface over the source implant layer and the plurality of gate implant layers.

12. The method of claim 10, wherein the substrate comprises a first concentration of a first type dopant.

13. The method of claim 12, wherein the drift layer comprises a second concentration of the first type dopant, the second concentration is less than the first concentration.

14. The method of claim 13, wherein the plurality of well implant layers comprise a third concentration of a second type dopant.

15. The method of claim 14, wherein the plurality of gate implant layers comprise a fourth concentration of the second type dopant, the fourth concentration is greater than the third concentration.

16. The method of claim 15, wherein the source implant layer comprises a fifth concentration of the first type dopant.

17. The method of claim 16, wherein the first type dopant comprises an n-type dopant and the second type dopant comprises a p-type dopant.

18. The method of claim 16, wherein the first type dopant comprises a p-type dopant and the second type dopant comprises an n-type dopant.
